(19) United States
(12) Patent Application Publication
(10) Pub. No.: US 2002/0076954 A1
(43) Pub. Date: Jun. 20, 2002

(54) Personal computer card having receptacle for mounting therein micro card

(76) Inventors: Kuan-Ming Chen, Hsinchu (TW); Tsung-Feng Chen, Taipei (TW); Chu-Fan Chen, Hsinchu (TW)

Correspondence Address: C. Frederick Koening III, Esquire, Volpe and Koenig, P.C., One Penn Center, Suite 400, 1617 John F. Kennedy Boulevard, Philadelphia, PA, 19103, US

(21) Appl. No.: 09/839,780

(22) Filed: Apr. 20, 2001

(30) Foreign Application Priority Data
Dec. 14, 2000 (CN) 00 2 64818.0

(51) Int. Cl. H05K 1/00; H01R 12/00

(52) U.S. Cl. 439/76.1

(57) ABSTRACT

A personal computer (PC) card has a receptacle for mounting therein a micro card to be inserted into a portable electronic device to perform connection and has an exposing edge when the personal computer card is inserted into the portable electronic device. The PC card includes an upper housing, a lower housing, and a frame placed between the upper housing and the lower housing and having the receptacle having a slit for replacably inserting therein the micro card.

### FIELD OF THE INVENTION

The present invention relates to a personal computer (PC) card, and more particularly to a PC card having a receptacle for mounting therein a micro card.

### BACKGROUND OF THE INVENTION

Because the design of a portable computer tends to reduce the volume thereof for increasing its portability, portable computers usually do not have enough space to accommodate the increasing and diverse peripheral apparatuses. Therefore, most peripheral apparatuses are externally connected to the portable computer to expand additional functions. Accordingly, a personal computer (PC) card is developed, and the size of the PC card is reduced as a credit card. The size of the peripheral apparatuses, such as add memory such as RAM (Random Access Memory), flash memory, I/O (input/output) application like a modem or a network interface card, and mass storage devices (for example hard disk), is also reduced in order to be conveniently carried and replaced. In addition, the corresponding slot is mounted in the portable computer and the PC card is plugged in and pulled out without disassembling the computer case. Some technical standards are constructed to promote the technique level of the PC card, for example:

PCMCIA (Personal Computer Memory Card International Association): this technical standard constructs some standards of the size specifications in order for the designers and the manufacturers to follow. For example, the length is 85.6 mm, the width is 54 mm, and the thickness is one selected from three specifications, Type I (3.3 mm), Type II (5 mm) and Type III (10.5 mm).

CFA (The CompactFlash Association): the CF (CompactFlash) card specification constructed by CFA is categorized into Type I and Type II, wherein the length, width and thickness of Type I is 43 mm (1.7″)×36 mm (1.4″)×3.3 mm (0.13″) respectively, and Type II is 43 mm (1.7″)×36 mm (1.4″)×5.5 mm (0.19″). Moreover, the CF card has 50 pins and on the other hand the PCMCIA specification has 68 pins.

Due to the fact that the Internet and wireless communication have been highly developed, using mobile communication devices and network to connect to the Internet for data transmission is the trend of future. Consequently, the PC card combined with the functionality of traditional wired modem and the wireless data (e.g. wireless communication and Wireless Application Protocol, WAP) for Internet is generated therewith. Functional block diagram of the circuit is shown in FIG. 1. The circuit includes an antenna 11, a radio frequency (RF) signal receiving module 12, a radio frequency (RF) signal transmitting module 13, an intermediate frequency (IF) signal receiving module 14, an intermediate frequency (IF) signal transmitting module 15, a mobile station chipset 16 and a signal connector 17 conforming to the standards of the PC card such as PCMCIA specification (68 pins) or CF card (50 pins). Moreover, present mobile phone networks records the subscriber related data/information by means of SIM (Subscriber Identification Module). The subscriber identification module is usually made of a micro SIM card which has a size of 18 mm×28 mm×0.8 mm in GSM (Global System for Mobile Communication) and other systems. Accordingly, The PC card for achieving the foregoing functions-combining the wired modem and the wireless receiving-transmitting functions (i.e. wireless communication) needs to contain a SIM card receptacle to be mounted therein and coupled to a circuit thereof.

In the specifications of U.S. Pat. Nos. 6,075,706 and 6,053,748, a PC card having a receptacle for mounting therein a SIM card is disclosed. The PC card body is formed of an upper and a lower metal housings in addition to a mounted circuit board therein. The difference between the U.S. Pat. No. 6,075,706 and the U.S. Pat. No. 6,053,748 is the position of the inserted hole in the SIM card. What the U.S. Pat. No. 6,075,706 discloses is disposed in the top of the upper metal housing and what the U.S. Pat. No. 6,053,748 discloses is deposed in a longer side of the upper metal housing near the joint with the lower metal housing. However, the above-mentioned patents both have the disadvantages of failing to pull and insert the SIM card easily. When the PC card is mounted in the slot of the portable computer and is operated, the inserted hole in the SIM card is hidden under the portable computer according to the foregoing prior arts. Therefore, the user must eject the PC card out of the slot first and proceed to replace the SIM card when the user wants to replace the SIM card (For example, one mobile telephone network has problems or bad connections and the user wants to change to another mobile telephone network), which is very inconvenient for the user. In addition, the connection interface between the PC card and the portable computer could be easily damaged because of frequently pulling and inserting the PC card. Furthermore, the receptive device for mounting therein the SIM card (i.e. the micro card) and the housing designs are quite complicated according to the above-mentioned patents, which increases great amount of the product cost.

It is therefore tried by the applicant to deal with the above situation encountered by the prior arts.

### SUMMARY OF THE INVENTION

It is an objective of the present invention to provide a PC card having a receptacle for mounting therein a micro card in which the micro card is capable of replaced directly without drawing out the PC card form a slot of the portable computer.

It is another objective of the present invention to provide a PC card having a receptacle for mounting therein a micro card in which the PC card has the simplified housing design for reducing the PC card damage possibility.

According to the present invention, the personal computer (PC) card has a receptacle for mounting therein a micro card to be inserted into a portable electronic device to perform connection and has an exposing edge when the personal computer card is inserted into the portable electronic device. The PC card includes an upper housing, a lower housing, and a frame placed between the upper housing and the lower housing and having the receptacle with a slit for replacably inserting therein the micro card.

Preferably, each of the upper housing and the lower housing is made of metal.

Preferably, the receptacle is for a Subscriber Identification Module (SIM).

Preferably, a space is formed between the edge of the slit and an exposing portion of the micro card inserted in the receptacle is remained, thereby performing an ejection function.

Preferably, the present invention further includes an ejection device for ejecting an exposing portion of the micro card out of the slit, thereby performing an ejection function.

The dimensions of the PC card preferably are based on the PCMCIA (Personal Computer Memory Card International Association) Specification which the length is 85.6 mm, the width is 54 mm, and the thickness is one selected form a group consisting of Type I (3.3 mm), Type II (5 mm) and Type III (10.5 mm).

The dimensions of the micro card preferably are based on the Specification of Subscriber Identification Module (SIM) card of Global System for Mobile (GSM) at a size of 18 mm×28 mm×0.8 mm.

Preferably, the PC card performs functions of wireless message switching and Wireless Application Protocol (WAP).

Certainly, the dimensions of the PC card can be based on the Specification of CompactFlash (CF) card which the length is 43 mm, the width is 36 mm, and the thickness is one selected form Type I (3.3 mm) and Type II (5.5 mm).

Certainly, the dimensions of said PC card can be based on the Specification of Security Digital (SD) card at the dimensions of 32 mm ×24 mm×2.1 mm.

The present invention may best be understood through the following description with reference to the accompanying drawings, in which:

### BRIEF DESCRIPTION OF THE DRAWINGS

FIG. 1 is a function block diagram of PC card circuit for integrating with a modem and a wireless communication function;

FIGS. 2(a) and 2(b) respectively are top and side views showing a type I fame of a PC card having a receptacle for mounting therein a micro card according to a preferred embodiment of the present invention;

FIGS. 3(a) and 3(b) respectively are top and side views showing a type II fame of a PC card having a receptacle for mounting therein the micro card according to a preferred embodiment of the present invention;

FIGS. 4(a), 4(b) and 4(c) are schematic views showing a slit for replacably inserting a micro card therein according to a preferred embodiment of the present invention; and

FIGS. 5(a), 5(b) and 5(c) are schematic views showing three preferred ejection devices according to the present invention.

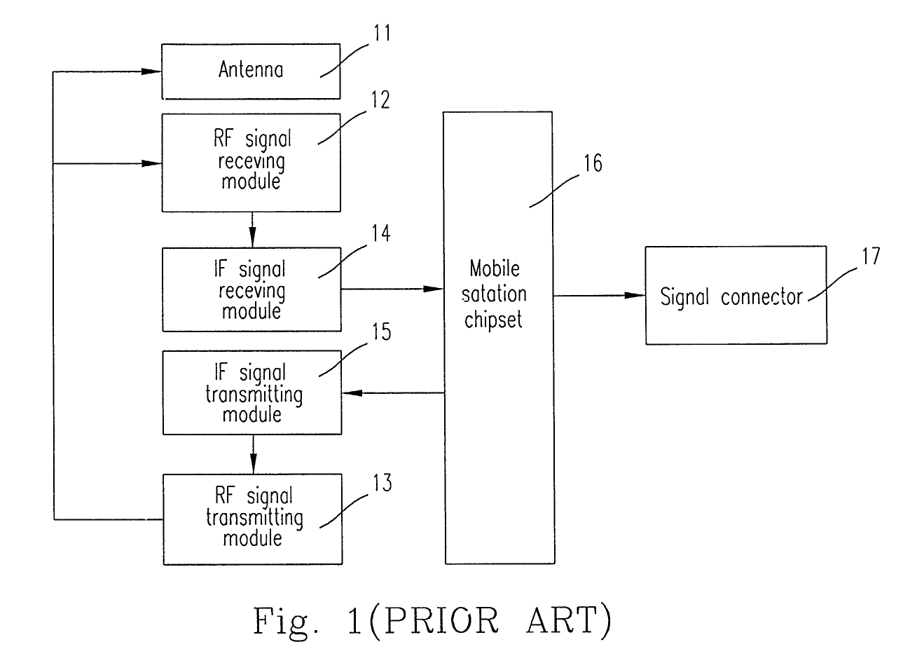

### DETAILED DESCRIPTION OF THE PREFERRED EMBODIMENTS

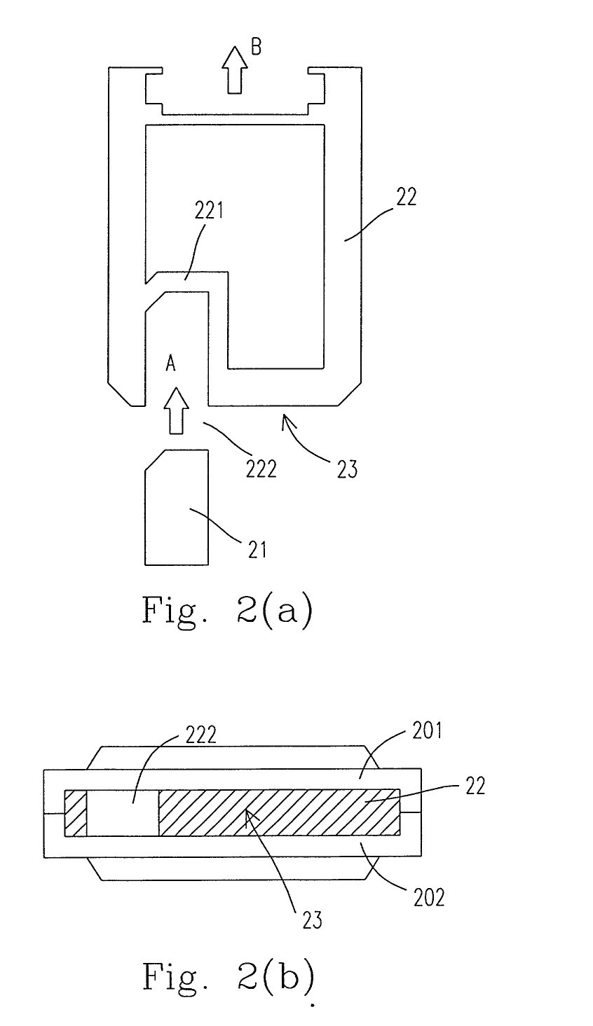

Please refer to FIGS. 2(a) and 2(b). The top and side views of type I frame for a PC card has a receptacle to mount therein a micro card according to a preferred embodiment of the present invention. Referring to FIG. 2(a), a micro card 21 is inserted into a receptacle 221 of a frame 22 along the direction of the arrow A. The frame 22 is placed between an upper housing 201 and a lower housing 202 which are made of metal, as can be shown in FIG. 2(b). Moreover, a circuitry (not shown) composed of functional circuits is mounted in a space on the frame 22 placed between the upper hosing 201 and the lower housing 202. Furthermore, the PC card is inserted into a slot of a portable computer (not shown) along the direction of the arrow B shown in FIG. 2(a) and an exposing edge 22 is formed. The important characteristic of the present invention is that a space is formed between the edge of the slit 222 and an exposing portion 23 of the micro card 21 inserted in the receptacle 221, thereby performing an ejection function. Then, the user can replace the micro card without drawing out the PC card from the portable computer, which is very convenient for the user. The PC card can avoid being frequently drawn out from and inserted to the portable computer. Furthermore, the simplified PC card construction design in the present invention can reduce the damage possibility thereof to increase the life of the PC card.

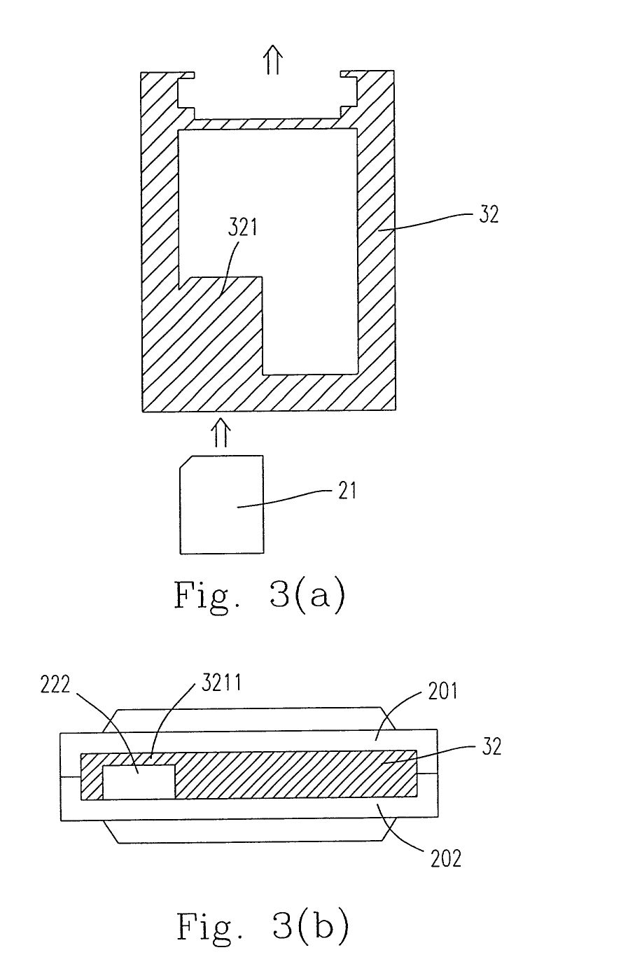

FIGS. 3(a) and 3(b) respectively show the top and side views of a type II frame for the PC card according to another preferred embodiment of the present invention. The structure of the type II frame 32 is the same as that of the type I frame 22, except that the receptacle 321 of the type II frame 32 has a upper cover 3211 which can be made of all possible material. When the micro card 21 is inserted into the receptacle 321, a salient (not shown) disposed on a micro card connector (not shown) corresponding to the circuitry will be slightly pressed downwards. Accordingly, a reacting force generated from the salient will allow the micro card 21 to be upwards against the upper cover 3211, and further fixes the micro card 21 to prevent the micro card 21 from falling off. As for the type I frame 22 in FIGS. 2(a) and 2(b), the reacting force generated from the salient can also allow the micro card 21 to be upwards against the upper housing 201 and prevent the micro card 21 from falling off. Therefore, either type I frame or type II frame of the PC card can provide the function for the user to replace the micro card 21 without drawing-out the PC card form the slot of the portable computer and is more convenient than the prior art. Moreover, the type I and type II frames are capable of providing the better anti-twisted force for the PC card.

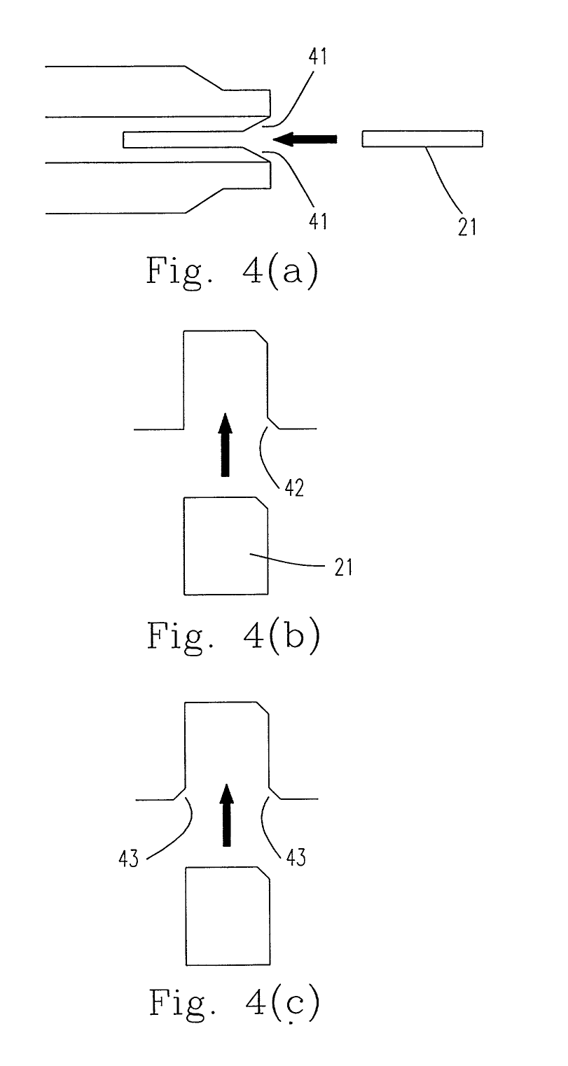

Please refer to FIGS. 4(a), 4(b), and 4(c). The schematic views show a slit 222 of the PC having the receptacle for mounting therein the micro card according to a preferred embodiment of the present invention. The slit 222 can provides the function for the user to easily draw out the micro card 21 mounted in the receptacle 221. The edge around the slit 222 have varied recesses 41, corners 42, 43 and a space between the exposing portion of the micro card 21 and the edge for the user to draw out the micro card 21 from the receptacle 221 by fingers or tweezers.

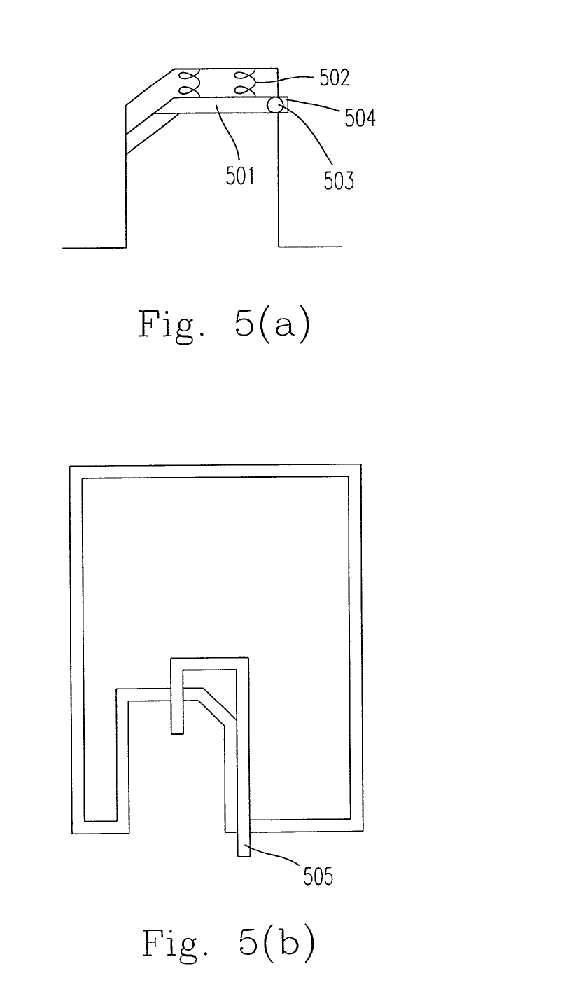

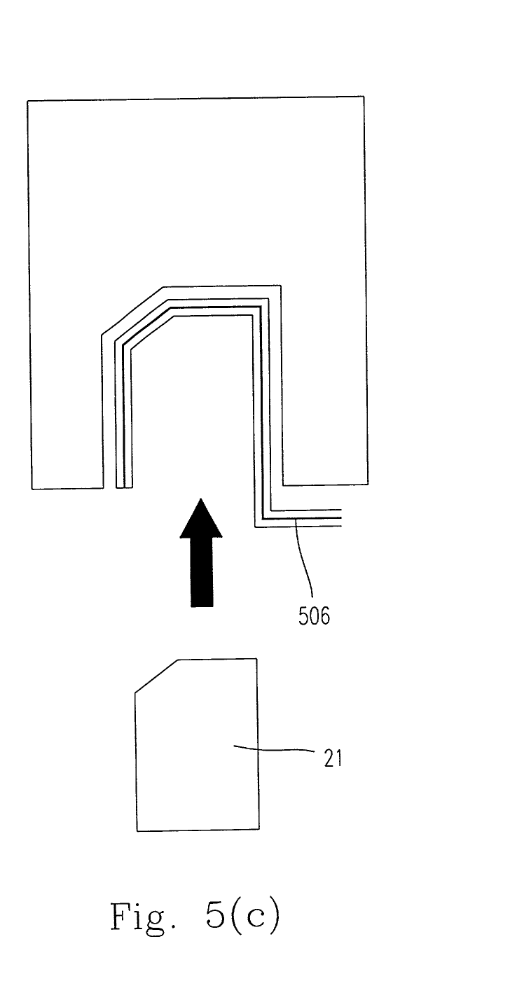

Furthermore, an ejection device can be mounted for ejecting the exposing portion of the micro card 21 out of the slit 222 to facilitate drawing the micro card 21 out from the receptacle 221. FIGS. 5(a) to 5(c) are schematic views showing three preferred ejection devices according to the present invention. The first preferred ejection device 50 shown in FIG. 5(a) is composed of a transverse bar 501 and a spring 502. The movement between the transverse bar 501 and the frame 22 is similar to the sliding action of a drawer. Consequently, the transverse bar 501 is moved toward the back end and the spring 502 is pressed when the micro card 21 is mounted in the receptacle 221. Moreover, a flexible protrusion 503 mounted in the end of the transverse bar 501 will be engaged with an opening 504 disposed in the frame 22 and the micro card 21 has been inserted in the receptacle 221. The micro card 21 inserted in the receptacle 221 has an exposing portion. When the user further pushes the exposing portion of the micro card 21 forward the receptacle 221, a reacting force is generated from the pressed spring 502. The reacting force makes the sliding transverse bar 501 out of the frame 22 engaged therewith and the micro card 21 is ejected. As to FIG. 5(b), the second preferred ejection device is composed of an ejecting shaft 505. The ejecting shaft 505 is made of a rigid material and the ejecting shaft 505 is pushed against the end of the receptacle 221 when the micro card 21 is inserted into the receptacle 221. Thus, the micro card 21 is taken out by pulling out the ejecting shaft 505. Certainly, the ejecting shaft 505 can be made of a casing pipe and a plastic or flexible core material. When the micro card 21 is inserted, the core material of the ejecting shaft 505 will be pushed against the base of the receptacle 221. The micro card 21 is taken out by pressing the core material. Referring to FIG. 5(c), the third preferred ejection device is formed of a lever 506. The shape of the lever 506 matches the micro card 21 to be inserted therein. When the micro card 21 is inserted into the receptacle 221, the lever 506 will be pushed against the back end. The micro card 21 is taken out by pulling out the lever 506.

The dimensions of the above-mentioned PC card preferably meet the requirements of the Specification of PCMCIA, wherein the length is 86.5 mm, the width is 54 mm and the thickness is one selected form a group consisting of Type I (3.3 mm), Type II (5 mm) and Type III (10.5 mm). Furthermore, the PC card is also in accordance with the Specification of CF (CompactFlash) card constructed in The CompactFlash Association (CFA) wherein the CF card is grouped into Type I and Type II. The dimension of Type I is at a size of 43 mm (1.7″) ×36 mm (1.4″)×3.3 mm (0.13″), and the dimension of Type II is a size of 43 mm (1.7″)×36 mm (1.4″)×5.5 mm (0.19″). The CF card has 50 pins is different with the 68-pin PCMCIA Specification. The micro card can be a SIM card for GSM (Global System for Mobile) mobile phone or a Secure Digital (SD) card, and the dimensions thereof is respectively about 18 mm×28 mm×0.8 mm and 32 mm×24 mm×2.1 mm. In addition, the circuitry is formed of the circuit board combined with the functions of the wireless communication and access to Internet.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What we claim is:

1. A personal computer (PC) card having a receptacle for mounting therein a micro card to be inserted into a portable electronic device to perform connection and having an exposing edge when said personal computer card is inserted into said portable electronic device, comprising:
an upper housing;
a lower housing; and
a frame placed between said upper housing and said lower housing and having said receptacle having a slit for replacably inserting therein said micro card.

2. The PC card according to claim 1, wherein said upper housing is formed of metal.

3. The PC card according to claim 1, wherein said lower housing is formed of metal.

4. The PC card according to claim 1, wherein said receptacle is a Subscriber Identification Module (SIM) receptacle.

5. The PC card according to claim 1, wherein a space is formed between the edge of said slit and an exposing portion of said micro card inserted in said receptacle, thereby performing an ejection function.

6. The PC card according to claim 1, further comprising an ejection device for ejecting an exposing portion of said micro card out of said slit, thereby performing an ejection function.

7. The PC card according to claim 1, wherein the dimensions of said PC card are based on the PCMCIA (Personal Computer Memory Card International Association) Specification which the length is 85.6 mm, the width is 54 mm, and the thickness is one selected form a group consisting of Type I (3.3 mm), Type II (5 mm) and Type III (10.5 mm).

8. The PC card according to claim 1, wherein the dimensions of said micro card are based on the Specification of Subscriber Identification Module (SIM) card of Global System for Mobile (GSM) at the dimensions of 18 mm×28 mm×0.8 mm.

9. The PC card according to claim 1, wherein said PC card performs functions of wireless communications.

10. The PC card according to claim 1, wherein the dimensions of said PC card are based on the Specification of CompactFlash (CF) card which the length is 43 mm, the width is 36 mm, and the thickness is one selected form Type I (3.3 mm) and Type II (5.5 mm).

11. The PC card according to claim 1, wherein the dimensions of said PC card are based on the Specification of Security Digital (SD) card at the dimensions of 32 mm×24 mm×2.1 mm.
